(19) United States
(12) Patent Application Publication
(10) Pub. No.: US 2026/0171179 A1
(43) Pub. Date: Jun. 18, 2026

(54) TESTING METHOD FOR MEMORY DEVICE

(71) Applicant: Powerchip Semiconductor Manufacturing Corporation, Hsinchu (TW)

(72) Inventors: Tsai-Ko Teng, Hsinchu City (TW); Chia-Yen Wu, Hsinchu County (TW)

(73) Assignee: Powerchip Semiconductor Manufacturing Corporation, Hsinchu (TW)

(21) Appl. No.: 19/045,445

(22) Filed: Feb. 4, 2025

(30) Foreign Application Priority Data
Dec. 12, 2024 (TW) 113148323

(51) Int. Cl. G11C 29/20; G11C 29/18

(52) U.S. Cl. CPC G11C 29/20; G11C 2029/1802

(57) ABSTRACT

A testing method for a memory device is provided. The memory device includes a memory array and a decoder circuit. The decoder circuit operates based on a first reference voltage. The memory array operates based on a second reference voltage. The testing method includes: dividing the memory array into memory blocks; adjusting a voltage value of at least one of the first reference voltage and the second reference voltage to sequentially access the memory blocks and receiving failed bit counts (FBCs) of the memory blocks after accessing operations; and counting a plurality of memory block numbers corresponding to different voltage values of the first reference voltage and/or the second reference voltage and the FBCs.

### CROSS-REFERENCE TO RELATED APPLICATION

This application claims the priority benefit of Taiwan application serial no. 113148323, filed on Dec. 12, 2024. The entirety of the above-mentioned patent application is hereby incorporated by reference herein and made a part of this specification.

### BACKGROUND

### Technical Field

The disclosure relates to a testing method of an electronic device, and particularly relates to a testing method for a memory device.

### Description of Related Art

In the related art, a testing method for a memory device may obtain the failed bit count (FBC) of the memory array of the memory device. However, the testing method does not analyze the failed bit status of the memory array based on the FBC. Therefore, how to provide a testing method that uses the FBC to analyze the failed bit status of the memory array is one of the research focuses of those skilled in the art.

### SUMMARY

The disclosure is directed to a testing method capable of using a failed bit count (FBC) to analyse a failed bit status of a memory array.

An embodiment of the disclosure provides a testing method for a memory device. The memory device includes a memory array and a decoder circuit. The decoder circuit operates based on a first reference voltage. The memory array operates based on a second reference voltage. The testing method includes the following steps. The memory array is divided into a plurality of memory blocks. A voltage value of at least one of the first reference voltage and the second reference voltage is adjusted to sequentially perform an accessing operation on the memory blocks, and a plurality of failed bit counts (FBCs) of the memory blocks after the accessing operation are received. A plurality of memory block numbers corresponding to a plurality of different voltage values of at least one of the first reference voltage and the second reference voltage and the FBCs are counted.

Based on the above descriptions, the testing method adjusts the voltage value of at least one of the first reference voltage and the second reference voltage to sequentially perform the accessing operation on the plurality of memory blocks to receive the plurality of FBCs of the memory blocks after the accessing operation. The testing method also counts the memory block numbers corresponding to the plurality of different voltage values of at least one of the first reference voltage and the second reference voltage and the FBCs. In this way, the testing method uses the FBCs to analyze the failed bit status of the memory array.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram illustrating testing of a memory device according to an embodiment of the disclosure.

FIG. 2 is a flow chart illustrating a testing method according to an embodiment of the disclosure.

FIG. 3 is a schematic diagram illustrating a memory block according to an embodiment of the disclosure.

FIG. 4 is a flow chart illustrating a testing method according to an embodiment of the disclosure.

FIG. 5 is a flow chart illustrating a testing method according to an embodiment of the disclosure.

FIG. 6 is a statistical chart illustrating memory block numbers according to an embodiment of the disclosure.

FIG. 7 is a flow chart illustrating a testing method according to an embodiment of the disclosure.

FIG. 8 is a flow chart illustrating a testing method according to an embodiment of the disclosure.

FIG. 9 is a flow chart illustrating a testing method according to an embodiment of the disclosure.

FIG. 10 is a flow chart illustrating a testing method according to an embodiment of the disclosure.

FIG. 11 is a flow chart illustrating a testing method according to an embodiment of the disclosure.

FIG. 12 is a flow chart illustrating a testing method according to an embodiment of the disclosure.

### DESCRIPTION OF THE EMBODIMENTS

Some embodiments of the disclosure will be described in detail with reference to the accompanying drawings. The component symbols cited in the following description will be regarded as the same or similar components when the same component symbols appear in different drawings. These embodiments are only a part of the disclosure and do not disclose all possible implementations of the disclosure. Rather, these embodiments are only examples within a scope of the patent application of the disclosure.

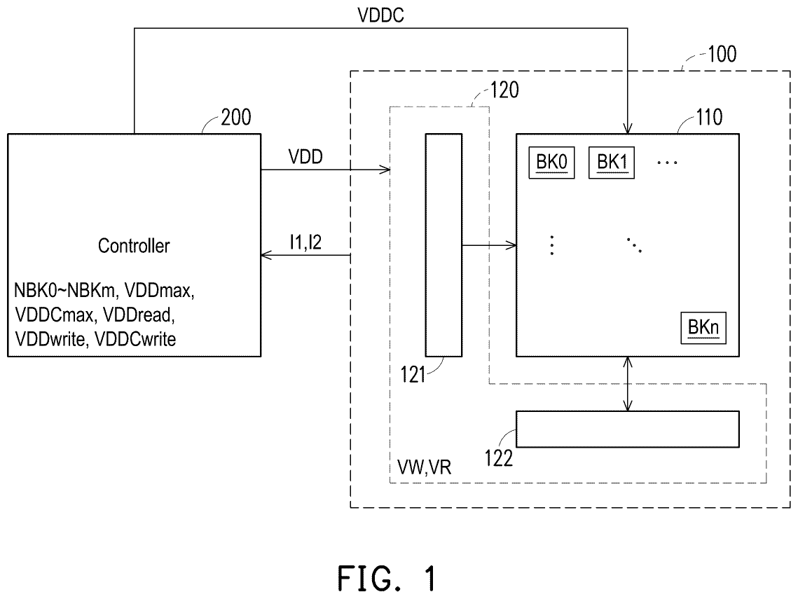

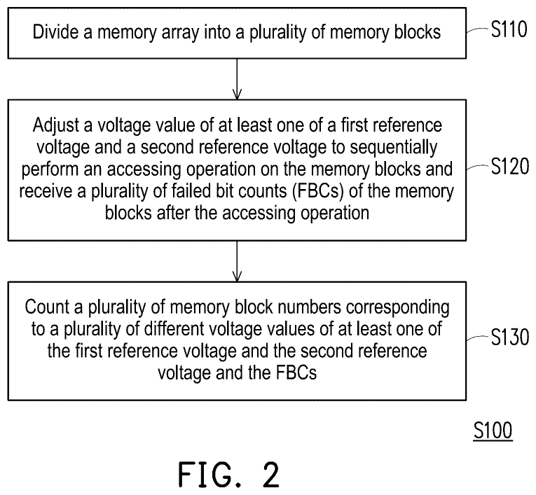

Referring to FIG. 1 and FIG. 2, FIG. 1 is a schematic diagram illustrating testing of a memory device according to an embodiment of the disclosure. FIG. 2 is a flow chart illustrating a testing method according to an embodiment of the disclosure. In the embodiment, a memory device 100 includes a memory array 110 and a decoder circuit 120. For example, the memory device 100 is a static random-access memory (SRAM), but the disclosure is not limited thereto. In this embodiment, the memory array 110 includes a plurality of memory cells. The decoder circuit 120 includes a row decoder 121 and a column decoder 122. The decoder circuit 120 operates according to a first reference voltage VDD. The first reference voltage VDD may be a reference power source of the row decoder 121 and the column decoder 122. The memory array 110 operates according to a second reference voltage VDDC. The second reference voltage VDDC may be a reference power source of the memory array 110.

In this embodiment, a testing method S100 is applicable to the memory device 100. For example, the testing method S100 may be executed by a controller 200. For example, the controller 200 may be a memory controller in the memory device 100 or a test circuit located outside the memory device 100.

In this embodiment, the testing method S100 includes steps S110 to S130. In step S110, the memory array 110 is divided into memory blocks BK0 to BKn. Taking the memory array 110 with 64 Mb as an example, the memory array 110 may be divided into 256 memory blocks BK0 to BKn (i.e., n is equal to “255”).

In step S120, the controller 200 adjusts a voltage value of at least one of the first reference voltage VDD and the second reference voltage VDDC to sequentially perform an accessing operation on the memory blocks BK0 to BKn, and receive a plurality of failed bit counts (FBCs) of the memory blocks BK0 to BKn after the accessing operation.

For example, the controller 200 fixes the voltage value of the second reference voltage VDDC. The controller 200 increments or decrements the voltage value of the first reference voltage VDD to sequentially perform the accessing operation on the memory blocks BK0 to BKn, and receives the plurality of FBCs of the memory blocks BK0 to BKn after the accessing operation.

For another example, the controller 200 fixes the voltage value of the first reference voltage VDD. The controller 200 increments or decrements the voltage value of the second reference voltage VDDC to sequentially perform the accessing operation on the memory blocks BK0 to BKn, and receives the plurality of FBCs of the memory blocks BK0 to BKn after the accessing operation.

For still another example, the controller 200 sets the voltage value of the first reference voltage VDD to a first voltage value. The controller 200 increments or decrements the voltage value of the second reference voltage VDDC to sequentially perform the accessing operation on the memory blocks BK0 to BKn, and receives a plurality of first FBCs of the memory blocks BK0 to BKn after the accessing operation. Then, the controller 200 increments or decrements the voltage value of the first reference voltage VDD to a second voltage value. The controller 200 resets the voltage value of the second reference voltage VDDC. Then, the controller 200 increments or decrements the voltage value of the second reference voltage VDDC to sequentially perform the accessing operation on the memory blocks BK0 to BKn, and receives a plurality of second FBCs of the memory blocks BK0 to BKn after the accessing operation, and so on.

In step S130, the controller 200 counts memory block numbers NBK0 to NBKm corresponding to a plurality of different voltage values of at least one of the first reference voltage VDD and the second reference voltage VDDC and the plurality of FBCs.

It should be noted that the testing method S100 adjusts the voltage value of at least one of the first reference voltage VDD and/or the second reference voltage VDDC to sequentially perform an accessing operation on the memory blocks BK0 to BKn to receive a plurality of FBCs of the memory blocks BK0 to BKn after the accessing operation. The testing method S100 also counts the memory block numbers NBK0 to NBKm corresponding to a plurality of different voltage values of the first reference voltage VDD and/or the second reference voltage VDDC and the different FBCs. In this way, the testing method S100 may use the FBCs to analyze a failed bit status of the memory array 110.

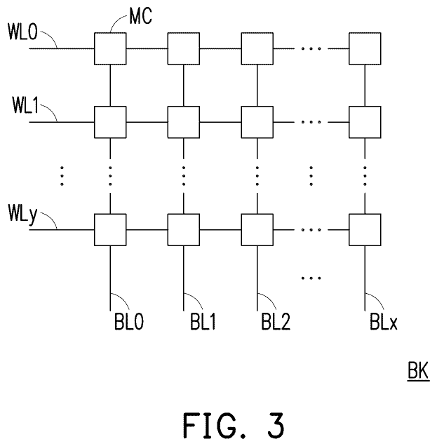

Referring to FIG. 1, FIG. 2, and FIG. 3, FIG. 3 is a schematic diagram illustrating a memory block according to an embodiment of the disclosure. In the embodiment, the memory block BK includes word lines WL0 to WLy, bit lines BL0 to BLx and a plurality of memory cells MC. During the accessing operation, one of the bit lines BL0 to BLx is selected as a selected bit line. The decoder circuit 120 performs a writing operation on the memory cells MC of a plurality of selected bit addresses connected to the selected bit line and different word lines, and performs a reading operation on the memory cells MC of the plurality of selected bit addresses connected to the selected bit line and different word lines.

For example, the bit line BL0 is selected as the selected bit line. Therefore, the decoder circuit 120 performs a writing operation and then performs a reading operation on all of the memory cells MC (or a memory column) connected to the bit line BL0. The decoder circuit 120 does not perform the accessing operation on the memory cells MC connected to the bit lines BL2 to BLx. In this way, the accessing operation of the memory column connected to the bit line BL0 will not be interfered by accessing operations of other memory columns.

Then, the bit line BL1 is selected as the selected bit line. Therefore, the decoder circuit 120 performs a writing operation and then performs a reading operation on all of the memory cells MC connected to the bit line BL1.

In the embodiment, in the writing operation, the decoder circuit 120 provides a writing voltage VW to the memory cells MC connected to the selected bit line. During the reading operation, the decoder circuit 120 pumps the writing voltage VW to a reading voltage VR, and provides the reading voltage VR to the memory cells MC connected to the selected bit line. After the writing operation, the decoder circuit 120 adjusts at least one of the first reference voltage VDD and/or the second reference voltage VDDC to perform reading operations on the memory cells MC of a plurality of selected bit addresses connected to the selected bit line and different word lines.

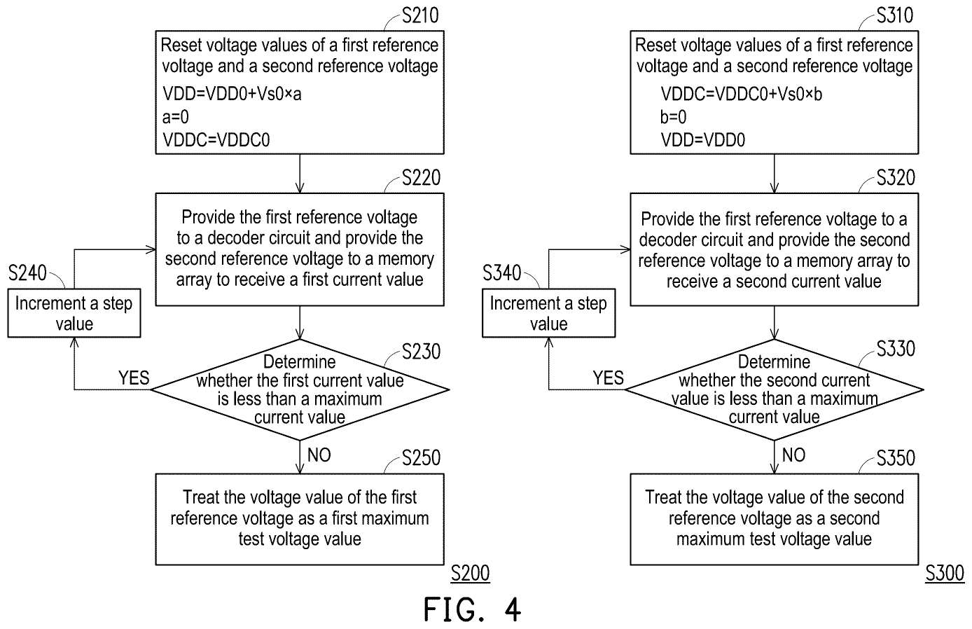

Referring to FIG. 1 and FIG. 4, FIG. 4 is a flow chart illustrating a testing method according to an embodiment of the disclosure. In the embodiment, the controller 200 further obtains a first maximum test voltage value VDDmax of the first reference voltage VDD and a second maximum test voltage value VDDCmax of the second reference voltage VDDC. Taking the embodiment as an example, the controller 200 uses the testing method S200 to obtain the first maximum test voltage value VDDmax, and uses the testing method S300 to obtain the second maximum test voltage value VDDCmax.

In the embodiment, the testing method S200 includes steps S210 to S250. In step S210, the controller 200 resets a voltage value of the first reference voltage VDD. For example, the voltage value of the first reference voltage VDD is equal to an initial voltage value VDD0 plus a product of a step voltage value Vs0 and a step value a (i.e., VDD=VDD0+Vs0×a). In step S210, the step value a is reset to “0”. Therefore, the voltage value of the first reference voltage VDD is equal to the initial voltage value VDD0. In addition, in step S210, a voltage value of the second reference voltage VDDC is also reset to the initial voltage value VDDC0.

In step S220, the controller 200 provides the first reference voltage VDD to the decoder circuit 120, and provides the second reference voltage VDDC to the memory array 110 to receive a first current value I1 (or referred to as a first operating current value) of the memory device 100.

In step S230, the controller 200 determines whether the first current value I1 is less than a maximum current value. For example, the maximum current value may be a maximum test current value (for example, 160 mA). The maximum test current value is lower than a maximum operating current value of the memory device 100 (for example, 200 mA). In step S230, when the first current value I1 is less than the maximum current value, the controller 200 increments the step value a (for example, a=a+1) in step S240 and returns to the operation of step S220. Therefore, the voltage value of the first reference voltage VDD is incremented. The first current value I1 is also incremented. In step S230, when the first current value I1 reaches the maximum current value, in step S250, the controller 200 treats the voltage value of the first reference voltage VDD as the first maximum test voltage value VDDmax. In other words, the first maximum test voltage value VDDmax corresponds to a voltage value of the maximum current value.

In the embodiment, the testing method S300 includes steps S310 to S350. In step S310, a voltage value of the second reference voltage VDDC is reset. For example, the voltage value of the second reference voltage VDDC is equal to the initial voltage value VDDC0 plus the product of the step voltage value Vs0 and a step value b (i.e., VDDC=VDDC0+Vs0×b). In step S310, the step value b is reset to “0”. Therefore, the voltage value of the second reference voltage VDDC is equal to the initial voltage value VDDC0. In addition, in step S310, the voltage value of the first reference voltage VDD is also reset to the initial voltage value VDD0.

In step S320, the controller 200 provides the first reference voltage VDD to the decoder circuit 120, and provides the second reference voltage VDDC to the memory array 110 to receive a second current value I2 (or referred to as a second operating current value) of the memory device 100.

In step S330, the controller 200 determines whether the second current value I2 is less than the maximum current value. In step S330, when the second current value I2 is less than the maximum current value, the controller 200 increments the step value b (for example, b=b+1) in step S340 and returns to the operation of step S320. Therefore, the voltage value of the second reference voltage VDDC is incremented. The second current value I2 is also incremented. In step S330, when the second current value I2 reaches the maximum current value, the controller 200 uses the voltage value of the second reference voltage VDDC as the second maximum test voltage value VDDCmax in step S350. In other words, the second maximum test voltage value VDDCmax corresponds to the voltage value of the maximum current value.

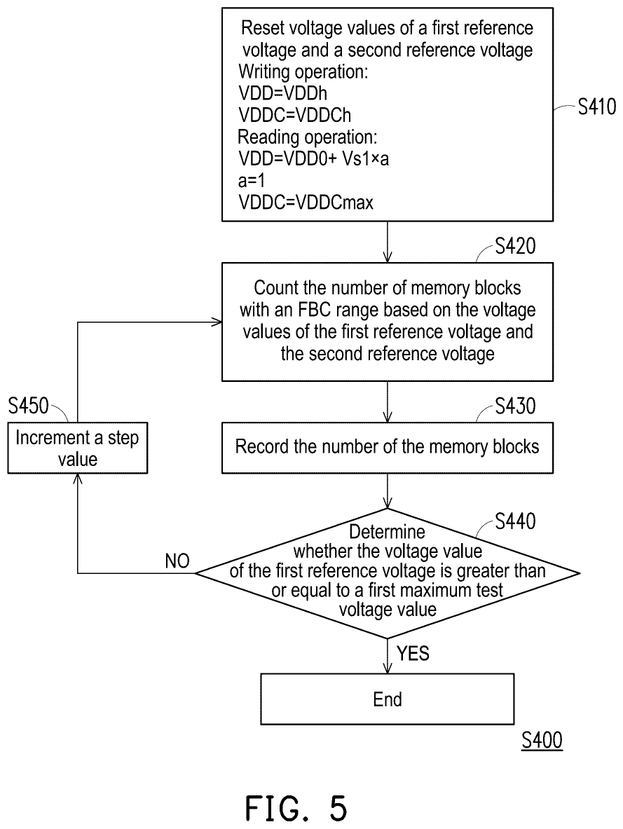

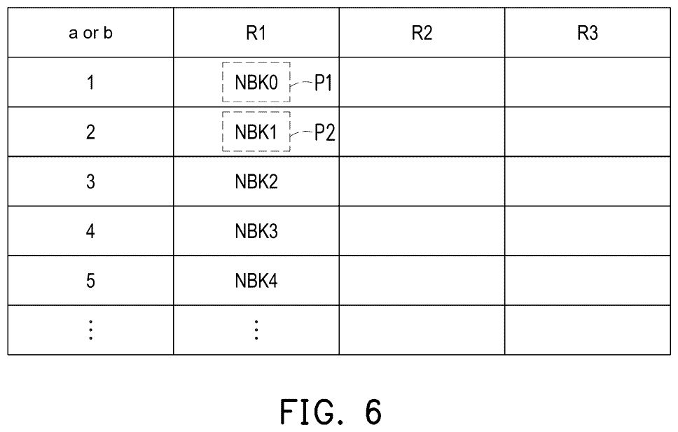

Referring to FIG. 1, FIG. 5, and FIG. 6, FIG. 5 is a flow chart illustrating a testing method according to an embodiment of the disclosure. FIG. 6 is a statistical chart of memory block numbers according to an embodiment of the disclosure. The statistical chart is, for example, represented by a table. The statistical chart is only used as an example, but the disclosure is not limited to the statistical chart. In the embodiment, a testing method S400 in FIG. 5 may be used to count the memory block numbers NBK0 to NBKm. The testing method S400 includes steps S410 to S450. In step S410, in a reading operation, the voltage value of the first reference voltage VDD is reset. For example, the voltage value of the first reference voltage VDD is equal to the initial voltage value VDD0 plus a product of a step voltage value Vs1 and the step value a (i.e., VDD=VDD0+Vs1×a). In step S410, the step value a is reset to “1”. Therefore, the voltage value of the first reference voltage VDD is equal to the initial voltage value plus the step voltage value “VDD0+Vs1”. In step S410, in the reading operation, the voltage value of the second reference voltage VDDC is set to the second maximum test voltage value VDDCmax. In a writing operation, the voltage value of the first reference voltage VDD is set to a setting voltage value VDDh. The voltage value of the second reference voltage VDDC is set to the setting voltage value VDDCh.

In step S420, the controller 200 counts a number of memory blocks with an FBC range R1 based on the voltage value of the first reference voltage VDD and the voltage value of the second reference voltage VDDC, and records the number of the memory blocks in step S430. The FBC range R1 represents that FBC is equal to “0”. For example, when the step value a is equal to “1”, the controller 200 may count a total of 255 memory blocks with the FBC range R1 in step S420 (i.e., NBK0=“255”). Therefore, in step S430, the controller 200 records the number of memory blocks. For example, in step S430, the controller 200 records the memory block number NBK0 at a position P1 of the statistical chart.

In step S440, the controller 200 determines whether the voltage value of the first reference voltage VDD is greater than or equal to the first maximum test voltage value VDDmax. When the voltage value of the first reference voltage VDD is less than the first maximum test voltage value VDDmax, the controller 200 increments the step value a (for example, a=a+1) in step S450 and returns to the operation of step S420. For example, when a is equal to “2”, the controller 200 may count a total of 254 memory blocks with the FBC range R1 in step S420 (i.e., NBK1=“254”). Therefore, in step S430, the controller 200 records the number of memory blocks. For example, in step S430, the controller 200 records the memory block number NBK1 at a position P2 of the statistical chart.

In the embodiment, in step S440, when the voltage value of the first reference voltage VDD is greater than or equal to the first maximum test voltage value VDDmax, the controller 200 completes counting the memory block numbers of the FBC range R1.

The controller 200 may execute the testing method S400 based on an FBC range R2 (for example, FBC≤“5”), and execute the testing method S400 based on an FBC range R3 (for example, FBC≤“10”), and so on.

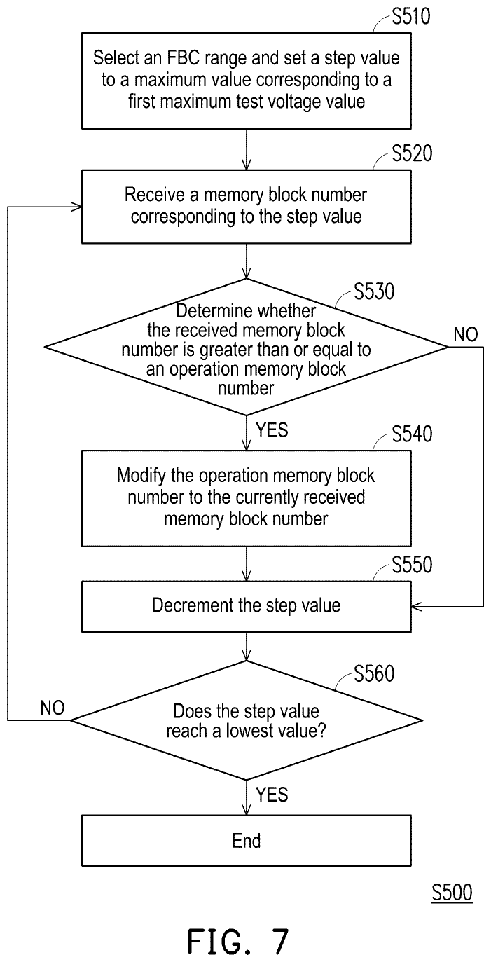

Referring to FIG. 1, FIG. 6, and FIG. 7, FIG. 7 is a flow chart illustrating a testing method according to an embodiment of the disclosure. In the embodiment, a testing method S500 of FIG. 7 may be used to determine an operation voltage value VDDread of the first reference voltage VDD when the voltage value of the second reference voltage VDDC is equal to the second maximum test voltage value VDDCmax during the reading operation. The controller 200 decrements the voltage value of the first reference voltage VDD from the first maximum test voltage value VDDmax based on the same FBC range to sequentially obtain a plurality of memory block numbers. When a memory block number NBK(m−1) is greater than or equal to a current operating memory block number NBKm, the controller 200 modifies the operating memory block number to the memory block number NBK(m−1). In addition, the controller 200 uses the voltage value of the first reference voltage VDD corresponding to the memory block number NBK(m−1) as the operation voltage value VDDread.

On the other hand, when the memory block number NBK(m−1) is less than the memory block number NBKm, the controller 200 continues to decrement the voltage value of the first reference voltage VDD to obtain a memory block number NBK(m−2) in sequence. When the memory block number NBK(m−2) is greater than or equal to the operating memory block number NKBm, the controller 200 modifies the operating memory block number to the memory block number NBK(m−2). In addition, the voltage value of the first reference voltage VDD corresponding to the memory block number NBK (m−2) is used as the operation voltage value VDDread.

In the embodiment, furthermore, the testing method S500 includes steps S510 to S560. In step S510, the controller 200 selects the FBC range and sets the step value a to the maximum value corresponding to the first maximum test voltage value VDDmax. The controller 200 sets the current operation voltage value VDDread to an initial value (for example, “0”). In addition, the controller 200 resets the previously received memory block number to the initial value (i.e., “0”).

The controller 200 receives the memory block number corresponding to the step value a in step S520, and determines a received memory block number in step S530. For example, in the FBC range R1, when the step value a is the maximum value, the memory block number is equal to “7”. Namely, when the voltage value of the first reference voltage VDD is equal to the first maximum test voltage value VDDmax, there are a total of seven memory blocks that meet the FBC range R1. When the voltage value of the first reference voltage VDD is equal to the first maximum test voltage value VDDmax, the controller 200 determines that the received memory block number is greater than the operating memory block number (for example, an initial value of the operating memory block number). Therefore, the controller 200 modifies the operating memory block number to the currently received memory block number “7” in step S540, and uses the voltage value of the first reference voltage corresponding to the memory block number as the operation voltage value VDDread. Then, the controller 200 decrements the step value a (for example, a=a−1) in step S550 and determines whether the step value a reaches the lowest value (for example, a=0) in step S560. When the step value a does not reach the lowest value (for example, a>0), the controller 200 returns to the operation of step S520.

In step S530, when the received memory block number is less than the operating memory block number, the controller 200 does not modify the operation voltage value VDDread and the operating memory block number, and decrements the step value a in step S550. In step S530, the selected FBC range may be adjusted or translated. In other words, during execution of the testing method S500, the selected FBC range may be changed based on a repair value. In other words, based on the same FBC range and the repair value, the controller 200 decrements the voltage value of the first reference voltage VDD from the first maximum test voltage value VDDmax to sequentially obtain a plurality of memory block numbers. The repair value may be 0 or any real number other than 0.

In step S560, when the step value a reaches the lowest value, the controller 200 ends the testing method S500. Therefore, based on the testing methods S400 and S500, the controller 200 determines the operation voltage value VDDread of the first reference voltage VDD. It should be noted that after the testing method S500 ends, the operating memory block number is the highest memory block number corresponding to the selected FBC range and the operation voltage value VDDread corresponding to the abovementioned highest memory block number. Namely, the operation voltage value VDDread of the first reference voltage VDD is the optimal reading operation voltage value of the selected FBC range.

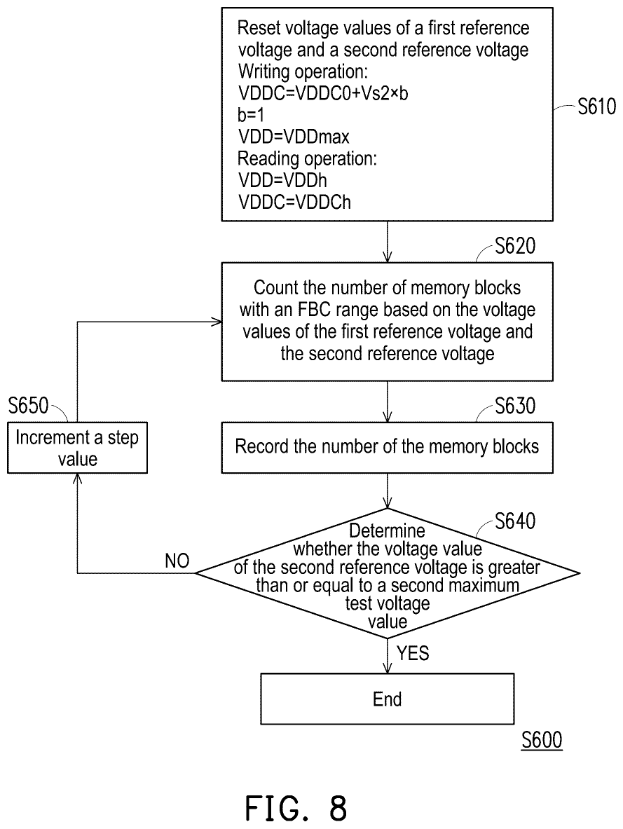

Referring to FIG. 1, FIG. 6, and FIG. 8, FIG. 8 is a flow chart illustrating a testing method according to an embodiment of the disclosure. In the embodiment, a testing method S600 in FIG. 8 may be used to count the memory block numbers NBK0 to NBKm. The testing method S600 includes steps S610 to S660. In step S610, in the writing operation, the voltage value of the second reference voltage VDDC is reset. For example, the voltage value of the second reference voltage VDDC is equal to the initial voltage value VDDC0 plus a product of a step voltage value Vs2 and the step value b (i.e., VDDC=VDDC0+Vs2×b). In step S610, the step value b is reset to “1”. Therefore, the voltage value of the second reference voltage VDDC is equal to the initial voltage value “VDDC0+Vs2”. In step S610, in the writing operation, the voltage value of the first reference voltage VDD is set to the first maximum test voltage value VDDmax. In the reading operation, the voltage value of the first reference voltage VDD is set to the setting voltage value VDDh. The voltage value of the second reference voltage VDDC is set to the setting voltage value VDDCh.

In step S620, the controller 200 counts the number of memory blocks with the FBC range R1 based on the voltage value of the first reference voltage VDD and the voltage value of the second reference voltage VDDC, and records the number of memory blocks in step S630. The FBC range R1 represents that FBC is equal to “0”. For example, when the step value b is equal to “1”, the controller 200 may count a total of 255 memory blocks with the FBC range R1 in step S620 (i.e., NBK0=“255”). Therefore, in step S630, the controller 200 records the memory block number NBK0.

In step S640, the controller 200 determines whether the voltage value of the second reference voltage VDDC is greater than or equal to the second maximum test voltage value VDDCmax. When the voltage value of the second reference voltage VDDC is less than the second maximum test voltage value VDDCmax, the controller 200 increments the step value b (for example, b=b+1) in step S650 and returns to the operation of step S620. For example, when b is equal to “2”, the controller 200 may count a total of 254 memory blocks with the FBC range R1 in step S620 (i.e., NBK1=“254”). Therefore, in step S630, the controller 200 records the memory block number NBK1.

In the embodiment, in step S640, when the voltage value of the second reference voltage VDDC is greater than or equal to the second maximum test voltage value VDDCmax, the controller 200 completes counting the memory block numbers of the FBC range R1.

The controller 200 may execute the testing method S600 based on the FBC range R2 (for example, FBC≤“5”), and execute the testing method S600 based on the FBC range R3 (for example, FBC≤“10”), and so on.

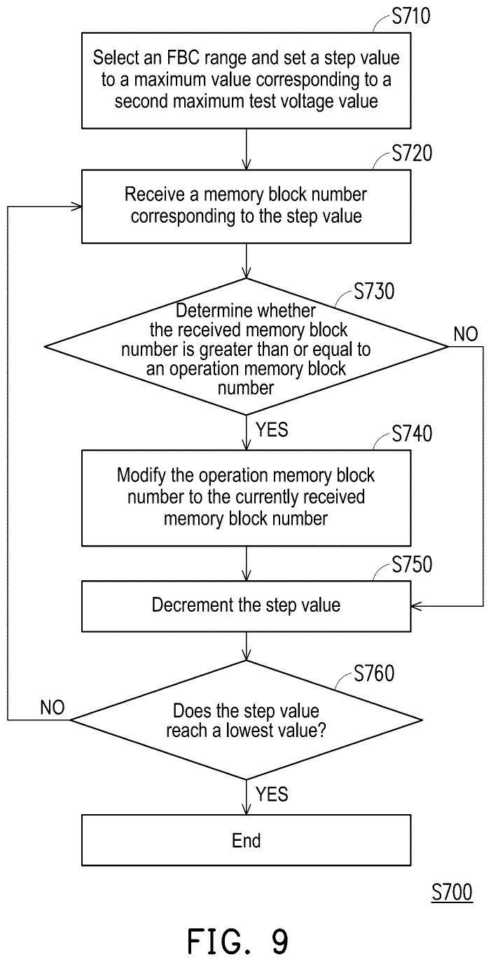

Referring to FIG. 1, FIG. 6, and FIG. 9, FIG. 9 is a flow chart illustrating a testing method according to an embodiment of the disclosure. In the embodiment, a testing method S700 of FIG. 9 may be used to determine an operation voltage value VDDCwrite of the second reference voltage VDDC when the voltage value of the first reference voltage VDD is equal to the first maximum test voltage value VDDmax during the writing operation. The controller 200 decrements the voltage value of the second reference voltage VDDC from the second maximum test voltage value VDDCmax based on the same FBC range to sequentially obtain a plurality of memory block numbers. When the memory block number NBKm is less than the memory block number NBK(m−1), the controller 200 uses the voltage value of the second reference voltage VDDC corresponding to the memory block number NBK(m−1) as the operation voltage value VDDCwrite.

On the other hand, when the memory block number NBKm is greater than or equal to the memory block number NBK(m−1), the controller 200 continues to decrement the voltage value of the second reference voltage VDDC to obtain the memory block number NBK(m−2) in sequence. When the memory block number NBKm is less than the memory block number NKB(m−2), the controller 200 uses the voltage value of the second reference voltage VDDC corresponding to the memory block number NBK (m−2) as the operation voltage value VDDCwrite.

In the embodiment, furthermore, the testing method S700 includes steps S710 to S750. In step S710, the controller 200 selects the FBC range and sets the step value b to the maximum value corresponding to the second maximum test voltage value VDDCmax. The controller 200 sets the current operation voltage value VDDCwrite to the initial value (for example, “0”). In addition, the controller 200 resets the previously received memory block number to the initial value (i.e., “0”).

The controller 200 receives the memory block number corresponding to the step value b in step S720, and determines a received memory block number in step S730. For example, in the FBC range R1, when the step value b is the maximum value, the memory block number is equal to “7”. Namely, when the voltage value of the second reference voltage VDDC is the second maximum test voltage value VDDCmax, there are a total of seven memory blocks that meet the FBC range R1. When the voltage value of the second reference voltage VDDC is second maximum test voltage value VDDCmax, the controller 200 determines that the received memory block number is greater than the initial value (i.e., the initial value of the operating memory block number). Therefore, the controller 200 modifies the operating memory block number to the currently received memory block number “7” in step S740, and uses the voltage value of the second reference voltage corresponding to the memory block number as the operation voltage value VDDCwrite. Then, the controller 200 decrements the step value b (for example, b=b−1) in step S750 and determines whether the step value b reaches the lowest value (for example, b=0) in step S760. When the step value b does not reach the lowest value (for example, b>0), the controller 200 returns to the operation of step S720.

In step S730, when the received memory block number is less than the operating memory block number, the controller 200 does not modify the operation voltage value VDDCwrite and the operating memory block number, and decrements the step value b in step S750. In step S730, the selected FBC range may be adjusted or translated. In other words, during execution of the testing method S700, the selected FBC range may be changed.

In step S760, when the step value b reaches the lowest value, the controller 200 ends the testing method S700. Therefore, based on the testing methods S600 and S700, the controller 200 determines the operation voltage value VDDCwrite of the second reference voltage VDDC. It should be noted that after the testing method S700 ends, the operating memory block number is the highest memory block number corresponding to the selected FBC range and the operation voltage value VDDCwrite corresponding to the abovementioned highest memory block number. The operation voltage value VDDCwrite of the second reference voltage VDDC is the optimal writing operation voltage value of the selected FBC range.

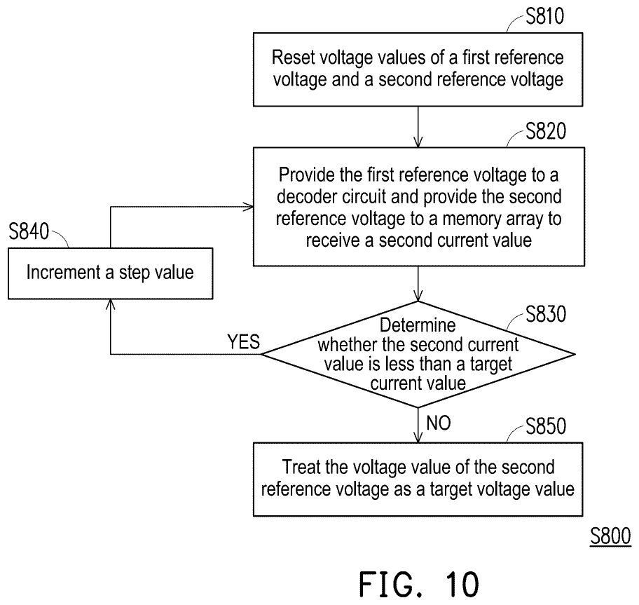

Referring to FIG. 1, FIG. 6, and FIG. 10, FIG. 10 is a flow chart illustrating a testing method according to an embodiment of the disclosure. In the embodiment, the controller 200 uses a testing method S800 to confirm a target voltage value VDDCt of the second reference voltage VDDC. The testing method S800 includes steps S810 to S850. In step S810, the voltage value of the second reference voltage VDDC is reset. For example, similar to step S310 of FIG. 4, the voltage value of the second reference voltage VDDC is equal to the initial voltage value VDDC0 plus a product of a step voltage value Vs0 and the step value b. In step S810, the step value b is reset to “0”. Therefore, the voltage value of the second reference voltage VDDC is equal to the initial voltage value VDDC0. In addition, in step S810, the voltage value of the first reference voltage VDD is also reset to the initial voltage value VDD0.

In step S820, the controller 200 provides the first reference voltage VDD to the decoder circuit 120, and provides the second reference voltage VDDC to the memory array 110 to receive the second current value I2 of the memory device 100.

In step S830, the controller 200 determines whether the second current value I2 is less than a target current value. In step S830, when the second current value I2 is less than the target current value, the controller 200 increments the step value b (for example, b=b+1) in step S840 and returns to the operation of step S820. Therefore, the voltage value of the second reference voltage VDDC is incremented. The second current value I2 is also incremented. In step S830, when the second current value I2 reaches the target current value, the controller 200 uses the voltage value of the second reference voltage VDDC as the target voltage value VDDCt in step S850.

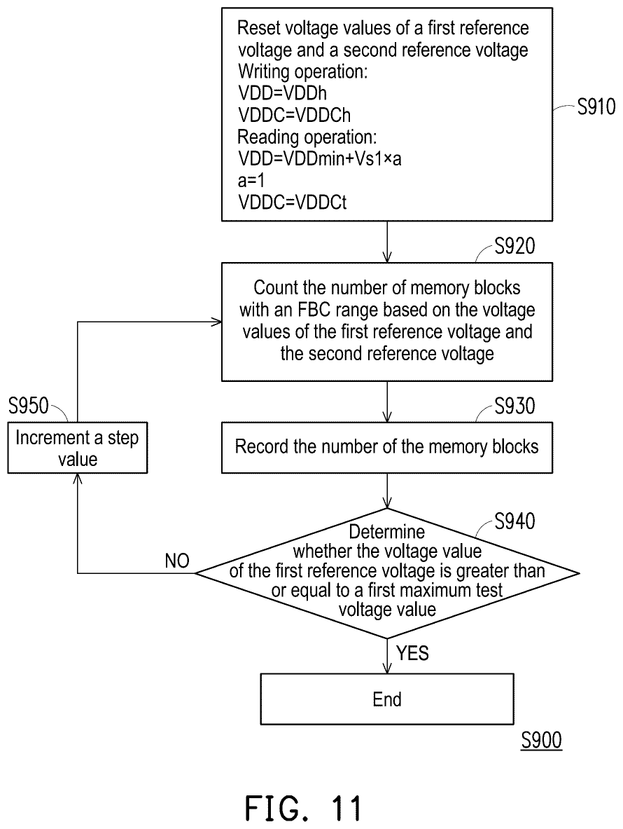

Referring to FIG. 1, FIG. 6, and FIG. 11, FIG. 11 is a flow chart illustrating a testing method according to an embodiment of the disclosure. A testing method S900 in FIG. 11 may be used to count the memory block numbers NBK0 to NBKm. The testing method S900 includes steps S910 to S950. In step S910, in the reading operation, the voltage value of the first reference voltage VDD is reset. For example, similar to step S410 of FIG. 5, the voltage value of the first reference voltage VDD is equal to the initial voltage value VDD0 (i.e., VDDmin) plus a product of the step voltage value Vs1 and the step value a. In step S910, the step value a is reset to “1”. Therefore, the voltage value of the first reference voltage VDD is equal to the initial voltage value plus the step voltage value “VDD0+Vs1”. In step S910, different to step S410, in the reading operation, the voltage value of the second reference voltage VDDC is set to the target voltage value VDDCt. In addition, in the writing operation, the voltage value of the first reference voltage VDD is set to the setting voltage value VDDh. The voltage value of the second reference voltage VDDC is set to the setting voltage value VDDCh.

The controller 200 counts the number of memory blocks with the FBC range R1 in step S920, and records the number of memory blocks in step S930.

In step S940, the controller 200 determines whether the voltage value of the first reference voltage VDD is greater than or equal to the first maximum test voltage value VDDmax. When the voltage value of the first reference voltage VDD is less than the first maximum test voltage value VDDmax, the controller 200 increments the step value a (for example, a=a+1) in step S950 and returns to the operation of step S920. In the embodiment, in step S940, when the voltage value of the first reference voltage VDD is greater than or equal to the first maximum test voltage value VDDmax, the controller 200 completes counting the memory block numbers of the FBC range R1.

The operation examples of steps S920 to S940 may be explained with reference to the examples of steps S420 to S440, and details thereof are not repeated here.

In addition, the controller 200 may execute the testing method S900 based on the FBC range R2 (for example, FBC≤“5”), and execute the test method S900 based on the FBC range R3 (for example, FBC≤“10”), and so on.

After completing the testing method S900, the controller 200 may determine the operation voltage value VDDread of the first reference voltage VDD based on the testing method S500 of FIG. 7. It should be noted that based on the testing method S900 and the testing method S500, when the voltage value of the second reference voltage VDDC is equal to the target voltage value VDDCt, the controller 200 may determine that the operation voltage value VDDread of the first reference voltage VDD in the reading operation is the optimal reading operation voltage value.

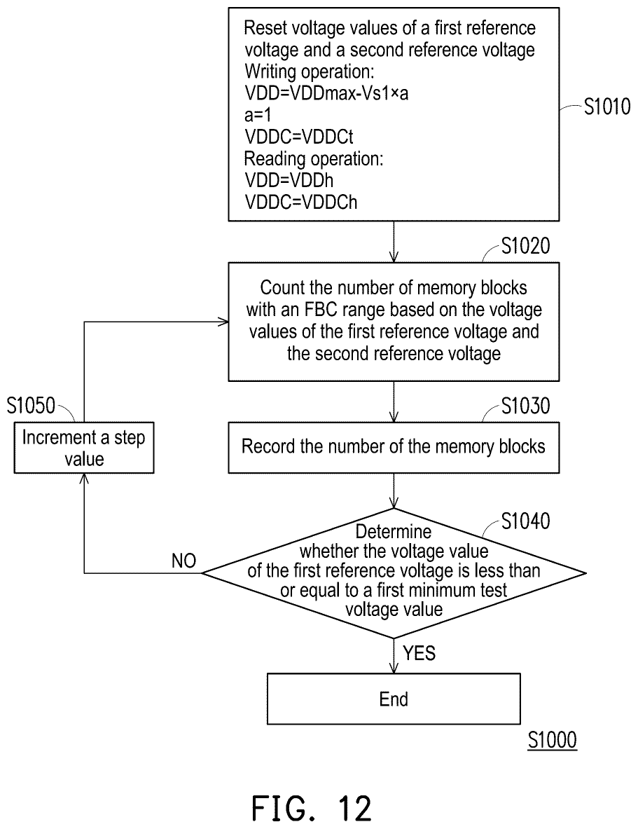

Referring to FIG. 1, FIG. 6, and FIG. 12, FIG. 12 is a flow chart illustrating a testing method according to an embodiment of the disclosure. In the embodiment, a testing method S1000 in FIG. 12 may be used to count the memory block numbers NBK0 to NBKm. The testing method S1000 includes steps S1010 to S1050. In step S1010, in the writing operation, the voltage value of the first reference voltage VDD is reset. For example, the voltage value of the first reference voltage VDD is equal to the first maximum test voltage value VDDmax minus a product of the step voltage value Vs1 and the step value a (i.e., VDD=VDDmax−Vs1×a). In step S1010, the step value a is reset to “1”. Therefore, the voltage value of the first reference voltage VDD is equal to the initial voltage value “VDDmax−Vs1”. In step S1010, in the writing operation, the voltage value of the second reference voltage VDDC is set to the target voltage value VDDCt. In the reading operation, the voltage value of the first reference voltage VDD is set to the setting voltage value VDDh. The voltage value of the second reference voltage VDDC is set to the setting voltage value VDDCh.

In step S1020, the controller 200 counts the number of memory blocks with the FBC range R1, and records the number of memory blocks in step S1030.

In step S1040, the controller 200 determines whether the voltage value of the first reference voltage VDD is less than or equal to the first minimum test voltage value. When the voltage value of the first reference voltage VDD is greater than the first minimum test voltage value, the controller 200 increments the step value a (for example, a=a+1) in step S1050 and returns to the operation of step S1020.

In the embodiment, in step S1040, when the voltage value of the first reference voltage VDD is less than or equal to the first minimum test voltage value, the controller 200 completes counting the memory block numbers of the FBC range R1.

The controller 200 may execute the testing method S1000 based on the FBC range R2 (for example, FBC≤“5”), and execute the test method S1000 based on the FBC range R3 (for example, FBC≤“10”), and so on.

After completing the testing method S1000, the controller 200 may determine the operation voltage value VDDwrite of the first reference voltage VDD based on the testing method S500 of FIG. 7. It should be noted that based on the testing method S1000 and the testing method S500, when the voltage value of the second reference voltage VDDC is equal to the target voltage value VDDCt, the controller 200 may determine that the operation voltage value VDDwrite of the first reference voltage VDD in the writing operation is the optimal writing operation voltage value. Therefore, based on the testing methods S900, S1000, and S500, the controller 200 may obtain the optimal writing operation voltage value and the optimal reading operation voltage value of the first reference voltage VDD corresponding to the target voltage value VDDCt of the second reference voltage VDDC.

In the embodiment, when the operation voltage value VDDread (i.e., the reading operation voltage value) is first determined, the controller 200 saves the operation voltage value VDDread. The controller 200 adjusts the first reference voltage VDD to obtain the operation voltage value VDDwrite (i.e., the writing operation voltage value) in the writing operation. In some embodiments, when the operation voltage value VDDwrite (i.e., the writing operation voltage value) is first determined, the controller 200 saves the operation voltage value VDDwrite. The controller 200 adjusts the first reference voltage VDD to obtain the operation voltage value VDDread (i.e., the reading operation voltage value) in the reading operation.

In addition, the operation voltage value VDDread (i.e., the reading operation voltage value) is smaller than the target voltage value VDDCt. The operation voltage value VDDwrite (i.e., the writing operation voltage value) is less than the target voltage value VDDCt. Once the operation voltage values VDDread and VDDwrite are determined, operation parameters of the memory blocks may be determined based on the operation voltage values VDDread and VDDwrite. In other words, when the voltage value of the second reference voltage VDDC is equal to the target voltage value VDDCt, the memory blocks NBK0 to NBKm may perform an accessing operation based on the operation voltage values VDDread and VDDwrite.

In view of the foregoing, the testing method adjusts the voltage value of at least one of the first reference voltage and the second reference voltage to sequentially perform the accessing operation on the plurality of memory blocks to receive the plurality of FBCs of the memory blocks after the accessing operation. The testing method also counts the plurality of memory block numbers corresponding to the plurality of different voltage values of the first reference voltage and/or the second reference voltage and the plurality of FBCs. In this way, the testing method may use the FBCs to analyze the failed bit status of the memory array. In addition, the testing method may also obtain the writing operation voltage value and the reading operation voltage value of the first reference voltage and/or the second reference voltage.

It will be apparent to those skilled in the art that various modifications and variations can be made to the disclosed embodiments without departing from the scope or spirit of the disclosure. In view of the foregoing, it is intended that the disclosure covers modifications and variations provided they fall within the scope of the following claims and their equivalents.

What is claimed is:

1. A testing method for a memory device, comprising a memory array and a decoder circuit, wherein the decoder circuit operates based on a first reference voltage, wherein the memory array operates based on a second reference voltage, the testing method comprising:
dividing the memory array into a plurality of memory blocks;
adjusting a voltage value of at least one of the first reference voltage and the second reference voltage to sequentially perform an accessing operation on the memory blocks and receiving a plurality of failed bit counts of the memory blocks after the accessing operation; and
counting a plurality of memory block numbers corresponding to a plurality of different voltage values of at least one of the first reference voltage and the second reference voltage and the failed bit counts.

2. The testing method according to claim 1, further comprising:
obtaining a first maximum test voltage value of the first reference voltage and a second maximum test voltage value of the second reference voltage.

3. The testing method according to claim 2, wherein the step of obtaining the first maximum test voltage value of the first reference voltage and the second maximum test voltage value of the second reference voltage comprises:
setting the voltage value of the second reference voltage;
incrementing the voltage value of the first reference voltage and receiving a first current value of the memory device; and
when the first current value reaches a maximum current value, treating the voltage value of the first reference voltage as the first maximum test voltage value.

4. The testing method according to claim 2, wherein the step of obtaining the first maximum test voltage value of the first reference voltage and the second maximum test voltage value of the second reference voltage comprises:
setting the voltage value of the first reference voltage;
incrementing the voltage value of the second reference voltage and receiving a second current value of the memory device; and
when the second current value reaches a maximum current value, treating the voltage value of the second reference voltage as the second maximum test voltage value.

5. The testing method according to claim 4, further comprising:
based on a same failed bit count and a repair value, decrementing the voltage value of the first reference voltage from the first maximum test voltage value to sequentially obtain a first memory block number and a second memory block number in the memory block numbers; and
when the second memory block number is greater than or equal to the first memory block number, modifying an operating memory block number to the second memory block number and treating the voltage value of the first reference voltage corresponding to the second memory block number as a first operation voltage value,
wherein the repair value is any real number.

6. The testing method according to claim 5, wherein the first operation voltage value is a reading operation voltage value generated by a reading operation in the accessing operation, wherein the testing method further comprises:
when the second current value reaches a target current value, treating the voltage value of the second reference voltage as a target voltage value; and
when the voltage value of the second reference voltage is equal to the target voltage value, determining the reading operation voltage value to be an optimal reading voltage value.

7. The testing method according to claim 6, wherein the first operation voltage value is a writing operation voltage value generated by a writing operation in the accessing operation, wherein the testing method further comprises:
when the second current value reaches a target current value, treating the voltage value of the second reference voltage as a target voltage value; and
when the voltage value of the second reference voltage is equal to the target voltage value, determining the writing operation voltage value to be an optimal writing voltage value.

8. The testing method according to claim 7, wherein
the reading operation voltage value is less than the target voltage value, and
the writing operation voltage value is greater than the target voltage value.

9. The testing method according to claim 7, further comprising:
determining operation parameters of the memory blocks according to the writing operation voltage value and the reading operation voltage value.

10. The testing method according to claim 7, further comprising:
when the reading operation voltage value is first determined, maintaining the reading operation voltage value and adjusting the first reference voltage in the writing operation to obtain the writing operation voltage value; and
when the writing operation voltage value is first determined, maintaining the writing operation voltage value and adjusting the first reference voltage in the reading operation to obtain the reading operation voltage value.

11. The testing method according to claim 5, further comprising:
when the second memory block number is less than the operating memory block number, continuing to decrementing the voltage value of the first reference voltage to sequentially obtain a third memory block number in the memory block numbers; and
when the third memory block number is greater than or equal to the operating memory block number, modifying the operating memory block number to the third memory block number and treating the voltage value of the first reference voltage corresponding to the third memory block number as a first operation voltage value.

12. The testing method according to claim 2, further comprising:
based on a same failed bit count, decrementing the voltage value of the second reference voltage from the second maximum test voltage value to sequentially obtain a first memory block number and a second memory block number in the memory block numbers; and
when the second memory block number is greater than or equal to the first memory block number, modifying an operating memory block number to the second memory block number and treating the voltage value of the second reference voltage corresponding to the second memory block number as a second operation voltage value.

13. The testing method according to claim 12, further comprising:
when the second memory block number is less than the operating memory block number, continuing to decrement the voltage value of the second reference voltage to sequentially obtain a third memory block number in the memory block numbers; and
when the third memory block number is greater than or equal to the operating memory block number, modifying the operating memory block number to the third memory block number and treating the voltage value of the second reference voltage corresponding to the third memory block number as a second operation voltage value.

14. The testing method according to claim 1, wherein the accessing operation comprises:
performing a writing operation on a plurality of memory cells of a plurality of selected bit addresses connected to a selected bit line and different word lines and performing a reading operation on the memory cells of the plurality of selected bit addresses connected to the selected bit line and different word lines.

15. The testing method according to claim 1, wherein the accessing operation comprises:
performing a writing operation on a plurality of memory cells of a plurality of selected bit addresses connected to a selected bit line and different word lines and adjusting at least one of the first reference voltage and the second reference voltage to perform a reading operation on the memory cells of the plurality of selected bit addresses connected to the selected bit line and different word lines.
